(19) United States
(12) Patent Application Publication
(10) Pub. No.: US 2021/0320106 A1
(43) Pub. Date: Oct. 14, 2021

(54) DRAM CAPACITOR TO STORAGE NODE'S LANDING PAD AND BIT LINE AIRGAP

(71) Applicant: Applied Materials, Inc., Santa Clara, CA (US)

(72) Inventor: Russell Chin Yee Teo, San Jose, CA (US)

(73) Assignee: Applied Materials, Inc., Santa Clara, CA (US)

(21) Appl. No.: 17/209,677

(22) Filed: Mar. 23, 2021

Related U.S. Application Data
(60) Provisional application No. 63/009,163, filed on Apr. 13, 2020.

(51) Int. Cl. H01L 27/108; G11C 5/06

(52) U.S. Cl. CPC H01L 27/10814; H01L 27/10823; H01L 27/10855; G11C 5/063; H01L 27/10885; H01L 27/10891; H01L 27/10876

(57) ABSTRACT

Memory devices and methods of forming memory devices are described. Specifically, dynamic random-access memory (DRAM) devices are provided with a capacitor landing pad able to connect a 6f² layout to a 4f² layout. In some embodiments, the capacitor landing pad has a plurality of air gaps.

### CROSS-REFERENCE TO RELATED APPLICATIONS

This application claims priority to U.S. Provisional Application No. 63/009,163, filed Apr. 13, 2020, the entire disclosure of which is hereby incorporated by reference herein.

### TECHNICAL FIELD

Embodiments of the present disclosure pertain to the field of electronic devices and electronic device manufacturing. More particularly, embodiments of the disclosure provide dynamic random-access memory (DRAM) with a capacitor landing pad able to connect a 6f² layout to a 4f² layout.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. There is a continuous desired to decrease the size of individual cells and to increase memory cell density to allow more memory to be included on a single memory chip, especially for densities greater than 256 Megabits. Limitations on cell size reduction include the passage of both active and passive word lines through the cell, the size of the cell capacitor, and the compatibility of array devices with non-array devices.

DRAM cells and circuits may be produced using semiconductor lithography. Modern trends in DRAM production include scaling DRAMs to ever smaller lithography sizes. As sizes are reduced, the spacing between the landing pads has to be decreased so that they can provide enough area for contact landing as the density of DRAM cells in a chip increase. The narrower spacing increases the fabrication difficulty due to the limitations of lithography overlay. Accordingly, methods of fabricating DRAM are required.

### SUMMARY

One or more embodiments of the disclosure are directed to a memory device. The memory device comprises: a substrate having a length extending along a first direction, a width extending along a second direction and a height extending along a third direction, the substrate comprising a channel and a dielectric material; a word line extending along the first direction, the word line comprising a word line metal and a first insulating material; a gate oxide extending along the first direction and in electrical communication with the word line; a bit line extending along the second direction, the bit line comprising a bit line metal and a second insulating material; and a landing pad on a top surface of the low-k dielectric and the bit line, the landing pad comprising a plurality of first angled pillars and a plurality of second angled pillars.

One or more embodiments are directed to a method of manufacturing a semiconductor device, the method comprising: forming a liner on a top surface of a substrate, a word line, and a bit line; forming a low-k dielectric layer on the liner and surrounding the bit line; forming channel layer on the low-k dielectric layer; forming a drain region adjacent the word line; forming a landing pad on the channel layer; and patterning the landing pad to form a plurality of first angled pillars and a plurality of second angled pillars.

Other embodiments of the disclosure are directed to a non-transitory computer readable medium including instructions, that, when executed by a controller of a processing chamber, causes the processing chamber to perform operations of: forming a liner on a top surface of a substrate, a word line, and a bit line; forming a low-k dielectric layer on the liner and surrounding the bit line; forming channel layer on the low-k dielectric layer; forming a drain region adjacent the word line; forming a landing pad on the channel layer; and patterning the landing pad to form a plurality of first angled pillars and a plurality of second angled pillars.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a top perspective view of a DRAM cell layout according to the prior art;

FIG. 1B illustrates a cross-section view of a DRAM cell layout according to the prior art;

FIG. 1C illustrates a top perspective view of a DRAM cell layout according to the prior art;

FIG. 1D illustrates a cross-section view of a DRAM cell layout according to one or more embodiments;

FIG. 1E illustrates a top perspective view of a DRAM cell layout according to one or more embodiments;

FIG. 1F illustrates a cross-section view of a DRAM cell layout according to one or more embodiments;

FIG. 2 illustrates a cross-section view of a DRAM device according to one or more embodiments;

FIG. 3 illustrates a cross-section view of a DRAM device according to one or more embodiments;

FIG. 4 illustrates a cross-section view of a DRAM device according to one or more embodiments;

FIG. 5 illustrates a cross-section view of a DRAM device according to one or more embodiments;

FIG. 6 illustrates a cross-section view of a DRAM device according to one or more embodiments;

FIG. 7 illustrates a cross-section view of a DRAM device according to one or more embodiments;

FIG. 8 illustrates a cross-section view of a DRAM device according to one or more embodiments;

FIG. 9 illustrates a cross-section view of a DRAM device according to one or more embodiments;

FIG. 10 illustrates a cross-section view of a DRAM device according to one or more embodiments;

FIG. 11 illustrates a cross-section view of a DRAM device according to one or more embodiments;

FIG. 12 illustrates a cross-section view of a DRAM device according to one or more embodiments;

FIG. 13 illustrates a cross-section view of a DRAM device according to one or more embodiments;

FIG. 14 illustrates a cross-section view of a DRAM device according to one or more embodiments;

FIG. 15 illustrates a cross-section view of a DRAM device according to one or more embodiments;

FIG. 16 illustrates a cross-section view of a DRAM device according to one or more embodiments;

FIG. 17 illustrates a cross-section view of a DRAM device according to one or more embodiments;

FIG. 18 illustrates a cross-section view of a DRAM device according to one or more embodiments;

FIG. 19 illustrates a cross-section view of a DRAM device according to one or more embodiments;

FIG. 20 illustrates a cross-section view of a DRAM device according to one or more embodiments;

FIG. 21 illustrates a cross-section view of a DRAM device according to one or more embodiments;

FIG. 22 illustrates a cross-section view of a DRAM device according to one or more embodiments; and

FIG. 23 illustrates a cross-section view of a DRAM device according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” or “wafer” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used herein, the term “bit line” or “source” refers to a layer of material that is an electrical conductor. In one or more embodiments, the channel comprises one or more silicon, polysilicon, epitaxial silicon, amorphous silicon, doped silicon, strained silicon, silicon on insulator (SOI), carbon doped silicon oxides, SiGe, germanium, Epi Ge, Epi SiGe, gallium arsenide, GaN, InP, carbon nanotube, and any other materials such as 2D TMD metals, metal oxides, metal nitrides, metal alloys, and other conductive materials, depending on the application. In one or more embodiments, the bit line includes, without limitation, growth silicon. Bit line may be exposed to in-situ or ex-situ pretreatment and post-treatment process to fuse, freeze, heat, microwave, polish, etch, reduce, oxidize, hydroxylate, anneal, UV cure, e-beam cure and/or bake the bulk or surface of the bit line. In addition to film processing directly on the surface or bulk structure of the bit line itself, in the present disclosure, any of the film processing steps disclosed may also be performed on an underlayer formed on the bit line as disclosed in more detail below, and the term “bit line surface” is intended to include such underlayer as the context indicates. Thus, for example, where a film/layer or partial film/layer has been deposited onto a bit line surface, the exposed surface of the newly deposited film/layer becomes the bit line surface.

As used herein, the term “capacitor” or “reservoir” refers to a layer of material that is an electrical charge storage dam. In one or more embodiments, the capacitor comprises one or more metal, TiN, SN, Zr, ZrO, ZrAlO, AlO, Al, Nb, NgO and any other materials such as 2D TMD metals MoS, metal oxides, metal nitrides, metal alloys, and other conductive materials, depending on the application. Capacitors include, without limitation, Zr. Capacitor may be exposed to a pretreatment process to fuse, freeze, heat, microwave, polish, etch, reduce, oxidize, hydroxylate, anneal, UV cure, e-beam cure and/or bake the surface. In addition to film processing directly on the surface or bulk structure of the capacitor itself, in the present disclosure, any of the film processing steps disclosed may also be performed on an underlayer formed on the Capacitor as disclosed in more detail below, and the term “capacitor surface” is intended to include such underlayer as the context indicates. Thus, for example, where a film/layer or partial film/layer has been deposited onto a capacitor surface, the exposed surface of the newly deposited film/layer becomes the capacitor surface.

As used herein, the term “active” or “memory layer” refers to a layer of material in which a channel, a bit line, a word line, or a capacitor can be made. In one or more embodiments, the memory layer comprises one or more of silicon or doped silicon. For example, in one or more embodiments, the memory layer is selected from one or more of Si, or IGZO (In—Ga—Zn Oxide).

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL) a word line is buried below the surface of a semiconductor substrate using a metal as a gate electrode.

Generally, when connecting a 6f² DRAM layout to a 4f² DRAM layout, the mismatched overlay between the island hard mask at the top of the storage node contact (SnC) is used to form the connection. This is problematic because of the limited surface contact area, with only about a 50% maximum landing pad (LP) to storage node post (SnP) contact area. Additionally, any overlay error between the hard mask and the storage node contact (SnC) results in even less surface contact area. High landing pad to storage node post metal resistance results because of the small contact area. One or more embodiments provide a device wherein no mismatched overlay hard mask is necessary. Two angled e-beam etch steps ensure about 100% of the landing pad to storage node post (SnP) surface contact, to reduced metal resistance by about 100%.

Traditionally, DRAM devices may have an integrated bit line air gap, which is formed by intended poor conformity of low-k chemical vapor deposition after bit line silicon nitride (SiN) trim. In such devices, the volume of the air gap is low, the BL-BL coupling is high, a taller aspect ratio capacitor is necessary, and the device is difficult and expensive to manufacture. Additionally, the device requires repeated cleaning steps because etchant and chemical mechanical planarization (CMP) residues seep out during storage node post (SnP) etch and metallization. Accordingly, one or more embodiments provides a landing pad having an integrated bit line air gap, which is formed by removal of low-k surround the bit line after the landing pad metallization steps are completed. In the device of one of more embodiments, the air gap volume is large, the BL-BL coupling is low, a smaller aspect ratio capacitor can be used, the cost of operation is lower, and there is a faster FabOut cycle time. Additionally, the device of one or more embodiments does not require an etchant and residue cleaning steps.

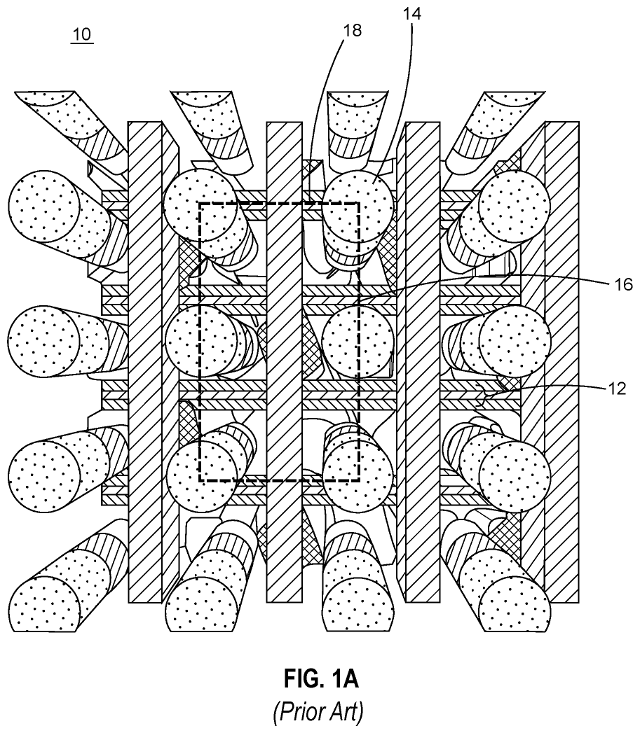

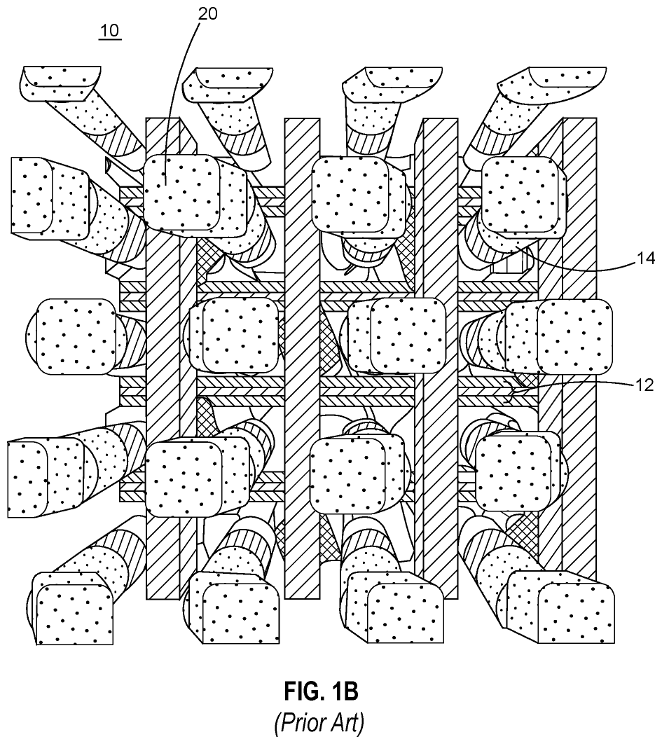

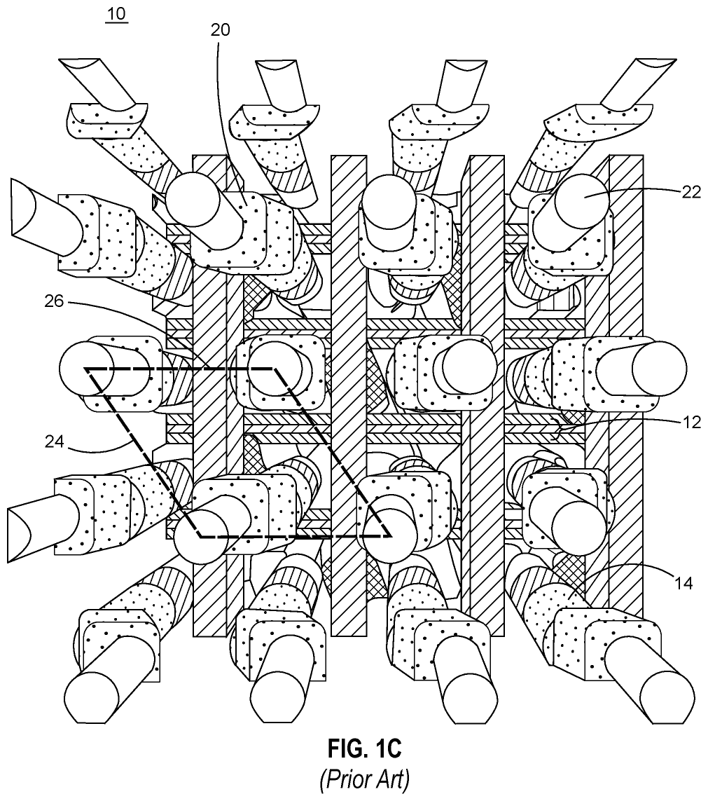

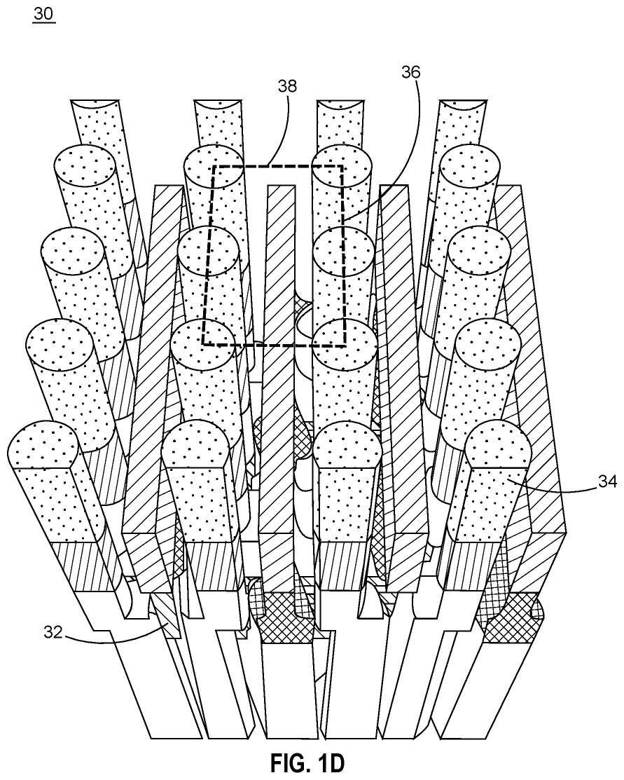

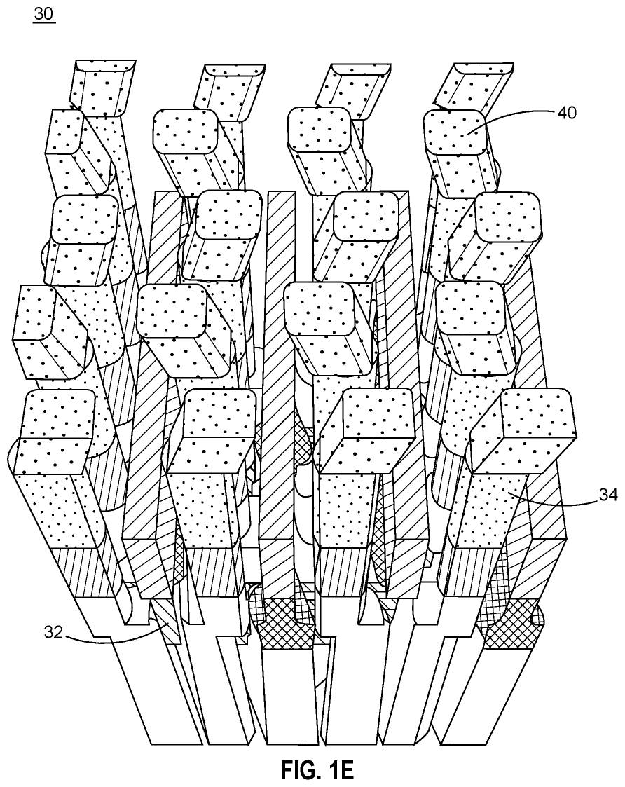

As illustrated in FIGS. 1D through 1F, which are top perspective views and cross-section views of DRAM cell layouts, a capacitor-on-bit line (CoB) architecture reduces the area of the unit cell compared with the conventional structure (FIGS. 1A through 1C), allowing more chips to be fabricated on one substrate. FIG. 1A illustrates a top perspective view of a DRAM cell 6f² layout 10 according to the prior art. The word line 12, bit line contact, bit line 14, storage node post, and storage node contact are arranged in a 6f² layout with 3f 16 and 2f 18. FIG. 1B illustrates a cross-section view of a DRAM cell 6f² layout 10, where landing pad 20 has been formed on top of the bit line 14, according to the prior art. The landing pad 20 is used to bridge the 6f² cell 10 to a 4f² cell. FIG. 1C illustrates a top perspective view of a 6f² DRAM cell layout 10 with a landing pad 20 bridged to a 4f² DRAM cell layout with a capacitor 22 according to the prior art. This bridging is problematic because the 6f² layout and the 4f² layout, with 2f 24 and 2f 26, cannot be directly connected.

FIG. 1D illustrates a top perspective view of a DRAM cell 6f² layout 30 according to one or more embodiments. The word line 32, bit line contact, bit line 34, storage node post, and storage node contact are arranged in a 6f² layout with 3f 36 and 2f 38. FIG. 1E illustrates a cross-section view of a DRAM cell 6f² layout 30 having a landing pad 40 according to one or more embodiments. FIG. 1F illustrates a top perspective view of a DRAM cell 6f² layout 30 with a landing pad 40 bridge to a DRAM cell 4f² layout according to one or more embodiments. The landing pad 40 of one or more embodiments advantageously permits a 6f² DRAM cell layout to be directly connected to a 4f² DRAM cell layout through a capacitor 42.

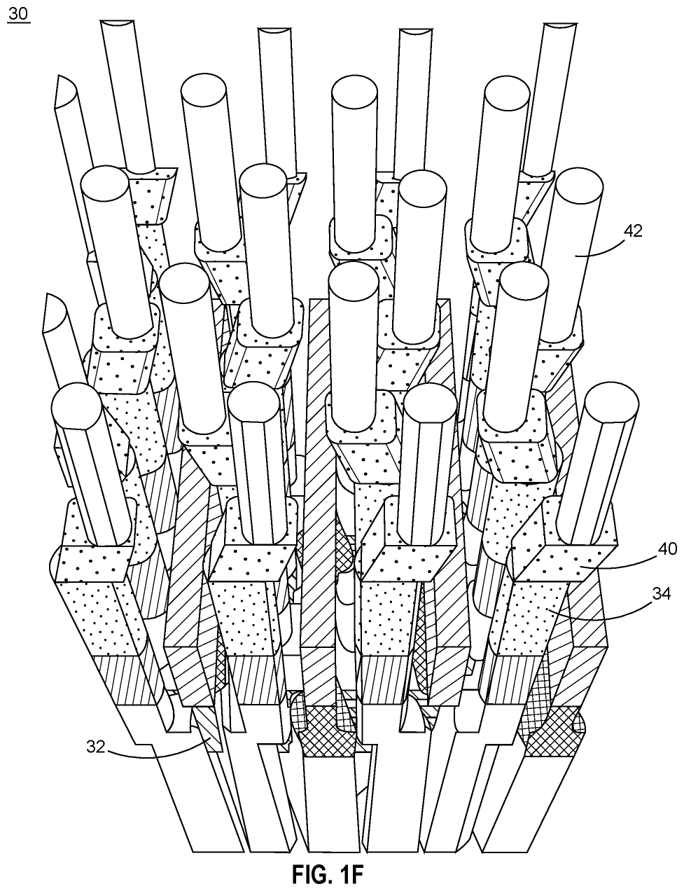

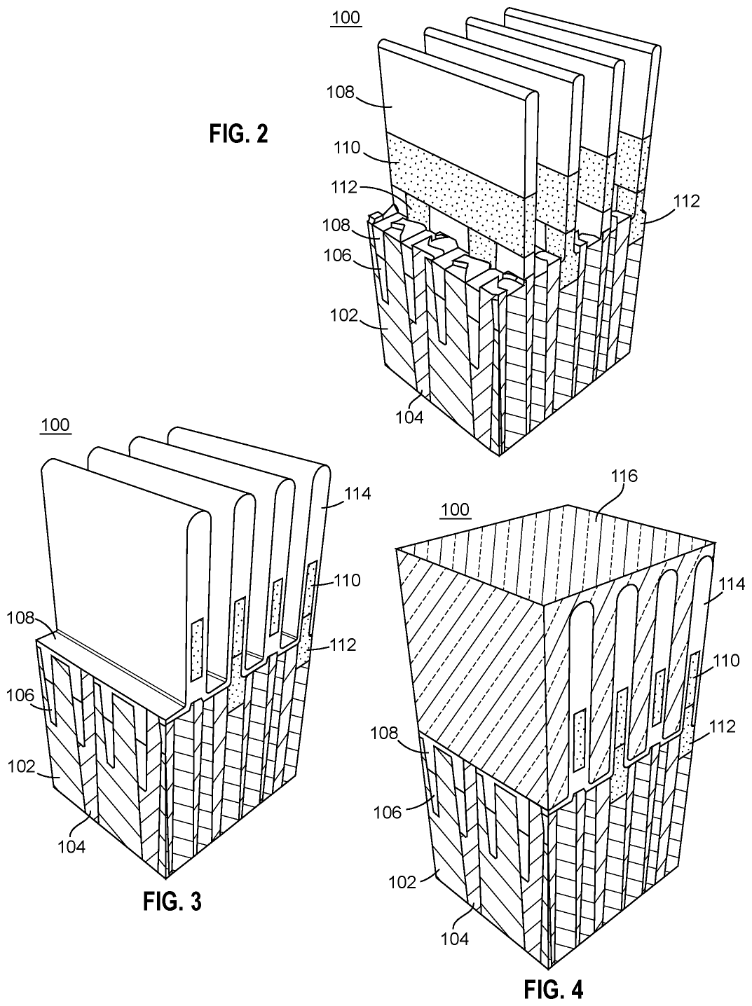

FIG. 2 illustrates a cross-section view of a DRAM device 100 according to one or more embodiments. The DRAM device 100 has a substrate 102 with a plurality of trenches filled with a dielectric material 104. A plurality of trenches filled with dielectric material 104 extends from a top surface of the substrate 102 through the substrate 104.

The substrate 102 can be any suitable substrate material. In one or more embodiments, the substrate 102 comprises a semiconductor material, e.g., silicon (Si), carbon (C), germanium (Ge), silicon germanium (SiGe), gallium arsenide (GaAs), indium phosphorus (InP), indium gallium arsenide (InGaAs), indium aluminum arsenide (InAlAs), other semiconductor materials, or any combination thereof. In some embodiments, substrate 102 is a semiconductor-on-isolator (SOI) substrate including a bulk lower substrate, a middle insulation layer, and a top monocrystalline layer. The top monocrystalline layer may comprise any material listed above, e.g., silicon (Si). In various embodiments, the substrate 102 can be, e.g., an organic, a ceramic, a glass, or a semiconductor substrate. Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present invention.

In some embodiments, the substrate 102 comprises a silicon channel. As used herein, the term “channel” refers to a layer of material that is an electrical conductor. In one or more embodiments, the channel comprises one or more silicon, polysilicon, amorphous silicon, doped silicon, strained silicon, silicon on insulator (SOI), carbon doped silicon oxides, SiGe, germanium, gallium arsenide, GaN, InP, carbon nanotube, and any other materials such as III-IV group, 2D TMD metals, metal oxides, metal nitrides, metal alloys, and other conductive materials, depending on the application. In one or more embodiments, the channel may be exposed to in-situ or ex-situ pretreatment and post-treatment processes to plate, fuse, freeze, heat, microwave, polish, etch, reduce, oxidize, hydroxylate, anneal, UV cure, e-beam cure and/or bake the surface or bulk of the channel. In addition to film processing directly on the surface or bulk structure of the channel itself, in one or more embodiments, any of the film processing steps disclosed may also be performed on an underlayer formed on the channel as disclosed in more detail below, and the term “channel surface” is intended to include such underlayer as the context indicates. Thus, for example, where a film/layer or partial film/layer has been deposited onto a channel surface, the exposed surface of the newly deposited film/layer becomes the channel surface.

With reference to FIG. 2, the dielectric material 104 fills the trenches. In one or more embodiments, the dielectric material 104 is deposited using any deposition technique known to one of skill in the art, such as, but not limited to, ALD, CVD, PVD, MBE, MOCVD, spin-on, shallow trench isolation (STI), or other deposition techniques known to the skilled artisan. In one or more embodiments, the dielectric material 104 forms an overburden (not illustrated) when deposited, and the overburden may be removed by any technique known to one of skill in the art, including, but not limited to chemical mechanical polishing (CMP), planarization, and the like. When the overburden is removed, the top surface of the gap dielectric material 104 is substantially coplanar with the top surface of the substrate 102.

As used in this manner, “substantially coplanar” means that the plane formed by the top surface of the gap fill material 112 is within ±5°, ±4°, ±3°, ±2° or ±1° of the plane formed by the top surface of the substrate 102. In some embodiments, the term “substantially coplanar” means that the planes formed plane formed by the top surface of the gap fill material 112 is within ±10 nm, ±5 nm, ±2.5 nm, ±1 nm or ±0.5 nm of the plane formed by the top surface of the substrate 102.

As used herein, the term “dielectric material” refers to a layer of material that is an electrical insulator that can be polarized in an electric field. In one or more embodiments, the dielectric layer comprises one or more of oxides, carbon doped oxides, silicon oxide (SiO), porous silicon dioxide (SiO₂), silicon oxide (SiO), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH). In one or more embodiments, the dielectric layer includes, without limitation, furnace, CVD, PVD, ALD and spin-on-coat (SoC) deposited films. In one or more embodiments, the dielectric layer may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the dielectric. In addition to film processing directly on the surface of the dielectric layer itself, in one or more embodiments, any of the film processing steps disclosed may also be performed on an underlayer formed on the dielectric layer as disclosed in more detail below, and the term “dielectric surface” is intended to include such underlayer as the context indicates. Thus, for example, where a film/layer or partial film/layer has been deposited onto a dielectric surface, the exposed surface of the newly deposited film/layer becomes the dielectric surface.

The device 100 comprises a gate oxide layer 106, a metal layer 110, an insulator layer 108, and a bit line contact 112. In some embodiments, the gate oxide layer 106 can be any suitable material known to the skilled artisan. The gate oxide layer 106 can be deposited using one or more deposition techniques known to one of ordinary skill in the art of microelectronic device manufacturing. In one or more embodiments, the gate oxide layer 106 is deposited using one of deposition techniques, such as, but not limited to, ALD, CVD, PVD, MBE, MOCVD, spin-on, or other deposition techniques known to the skilled artisan. In one or more embodiments, the gate oxide layer 106 comprises a low-K dielectric. In some embodiments, the low-K dielectric is selected from one or more of silicon, silicon oxide, silicon nitride, silicon oxynitride, silicon oxycarbide, silicon oxycarbonitride, doped silicon, doped silicon oxide, doped silicon nitride, doped silicon oxynitride, spin-on dielectrics, or a diffusion species growth. In one or more embodiments, gate oxide layer 106 comprises a silicon oxide.

In one or more embodiments, the gate oxide layer 106 has a thickness in a range of from about 1 nm to about 20 nm, including a range of from about 3 nm to about 18 nm, and including a range of from about 5 nm to about 15 nm.

As used herein, the term “word line” or “gate” or “gate oxide,” refers to a layer of material that is an electrical field generating or conductor material. In one or more embodiments, the gate oxide layer 106 comprises one or more polysilicon, amorphous silicon (Si), tungsten (W), ruthenium (Ru), cobalt (Co), high-k dielectric, and any other materials such as 2D TMD metals MoS, metal oxides, metal nitrides, metal alloys, and other conductive materials, depending on the application. In one or more embodiments, the gate oxide includes, without limitation, tungsten oxide (W). In one or more embodiments, the gate oxide layer 106 may be exposed to in-situ or ex-situ pretreatment and post-treatment process to fuse, freeze, heat, microwave, polish, etch, reduce, oxidize, hydroxylate, anneal, UV cure, e-beam cure and/or bake the metal surface & bulk. In addition to film processing directly on the surface or bulk structure of the gate oxide layer 106 itself, in the present disclosure, any of the film processing steps disclosed may also be performed on an underlayer formed on the gate oxide layer 106 as disclosed in more detail below, and the term “gate oxide layer surface” is intended to include such underlayer as the context indicates. Thus, for example, where a film/layer or partial film/layer has been deposited onto a gate oxide layer surface, the exposed surface of the newly deposited film/layer becomes the gate oxide layer surface.

In one or more embodiments, the metal layer 110 can be made of any suitable material known to the skilled artisan. In one or more embodiments, the metal layer 110 comprises a metal selected from one or more of copper (Cu), cobalt (Co), tungsten (W), titanium (Ti), molybdenum (Mo), nickel (Ni), ruthenium (Ru), silver (Ag), gold (Au), iridium (Ir), or platinum (Pt). In one or more specific embodiments, the metal layer 110 comprises a metal selected from one or more of cobalt (Co), tungsten (W), titanium (Ti), molybdenum (Mo), nickel (Ni), ruthenium (Ru), silver (Ag), iridium (Ir), or platinum (Pt). In other specific embodiments, the metal layer 110 comprises a metal selected from one or more of cobalt (Co), tungsten (W), titanium (Ti), molybdenum (Mo), or ruthenium (Ru).

In one or more embodiments, the insulator layer 108 can be made of any suitable material known to the skilled artisan. In one or more embodiments, the insulator layer 108 comprises one or more of oxides, carbon doped oxides, silicon oxide (SiO), porous silicon dioxide (SiO₂), silicon oxide (SiO), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH). In one or more embodiments, the insulator layer 108 includes, without limitation, furnace, CVD, PVD, ALD and spin-on-coat (SoC) deposited films. In one or more embodiments, the insulator layer 108 may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the insulator layer 108. In addition to film processing directly on the surface of the insulator layer 108 itself, in one or more embodiments, any of the film processing steps disclosed may also be performed on an underlayer formed on the insulator layer 108 as disclosed in more detail below, and the term “insulator surface” is intended to include such underlayer as the context indicates. Thus, for example, where a film/layer or partial film/layer has been deposited onto an insulator surface, the exposed surface of the newly deposited film/layer becomes the insulator surface.

FIG. 3 illustrates a cross-section view of a DRAM device 100 according to one or more embodiments. With reference to FIG. 3, a liner 114 is deposited on a top surface of the device 100. The liner 114 may be conformal or non-conformal. In one or more embodiments, the liner 114 comprises one or more of silicon oxide (SiO), silicon nitride (SiN), titanium nitride (TiN), titanium (Ti), tantalum (Ta), or tantalum nitride (TaN). In an embodiment, the liner 114 is deposited using an atomic layer deposition (ALD) technique. In one or more embodiments, the liner 114 is deposited using one of deposition techniques, such as but not limited to a CVD, PVD, MBE, MOCVD, spin-on, or other liner deposition techniques known to one of ordinary skill in the art of microelectronic device manufacturing. In one or more embodiments, the liner 114 serves as an etch stop layer.

In one or more embodiments, deposition of the liner 114 is substantially conformal. As used herein, a layer (e.g., liner) which is “substantially conformal” refers to a layer where the thickness is about the same throughout. A layer which is substantially conformal varies in thickness by less than or equal to about 5%, 2%, 1% or 0.5%.

FIG. 4 illustrates a cross-section view of a DRAM device 100 according to one or more embodiments. With reference to FIG. 4, a gap fill layer 116 is deposited on the liner 114. In one or more embodiment, the gap fill layer 116 may comprise any suitable material known to one of skill in the art. In one or more embodiments, the gap fill layer 116 comprises a low-k dielectric material.

In one or more embodiments, the gap fill layer 116 can be made of any suitable material known to the skilled artisan. In one or more embodiments, the gap fill layer 116 comprises one or more of oxides, carbon doped oxides, silicon oxide (SiO), porous silicon dioxide (SiO₂), silicon oxide (SiO), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH). In one or more embodiments, the gap fill layer 116 includes, without limitation, furnace, CVD, PVD, ALD and spin-on-coat (SoC) deposited films. In one or more embodiments, the gap fill layer 116 comprises silicon nitride (SiN). In one or more embodiments, the gap fill layer 116 may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the gap fill layer 116. In addition to film processing directly on the surface of the gap fill layer 116, in one or more embodiments, any of the film processing steps disclosed may also be performed on an underlayer formed on the gap fill layer 116, and the term “insulator surface” is intended to include such underlayer as the context indicates. Thus, for example, where a film/layer or partial film/layer has been deposited onto an insulator surface, the exposed surface of the newly deposited film/layer becomes the insulator surface.

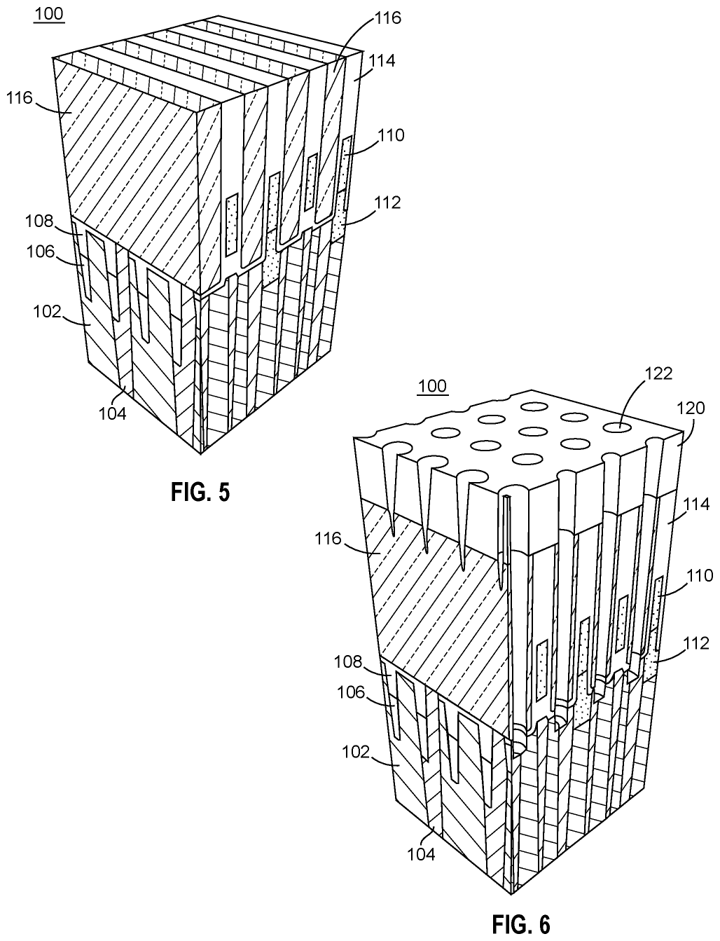

In one or more embodiments, the gap fill layer 116 forms an overburden 118 when deposited. FIG. 5 illustrates a cross-section view of a DRAM device 100 according to one or more embodiments. With reference to FIG. 5, the overburden 118 may be removed by any technique known to one of skill in the art, including, but not limited to chemical mechanical polishing (CMP), planarization, etch back, and the like. When the overburden 118 is removed, the top surface of the gap fill layer 116 is substantially coplanar with the top surface of the liner 114.

As used in this manner, “substantially coplanar” means that the plane formed by the top surface of the gap fill layer 116 is within ±5°, ±4°, ±3°, ±2° or ±1° of the plane formed by the top surface of the liner 114. In some embodiments, the term “substantially coplanar” means that the planes formed plane formed by the top surface of the gap fill layer 116 is within ±10 nm, ±5 nm, ±2.5 nm, ±1 nm or ±0.5 nm of the plane formed by the top surface of the liner 114.

FIG. 6 illustrates a cross-section view of a DRAM device 100 according to one or more embodiments. With reference to FIG. 6, a channel layer 120 is deposited on a top surface of the liner 114 and a top surface of the gap fill layer 116. The channel layer 120 comprises a layer of material that is an electrical conductor. In one or more embodiments, the channel layer 120 comprises one or more silicon, polysilicon, amorphous silicon, doped silicon, strained silicon, silicon on insulator (SOI), carbon doped silicon oxides, SiGe, germanium, gallium arsenide, GaN, InP, carbon nanotube, and any other materials such as III-IV group, 2D TMD metals, metal oxides, metal nitrides, metal alloys, and other conductive materials, depending on the application. In one or more embodiments, the channel layer 120 may be exposed to in-situ or ex-situ pretreatment and post-treatment processes to plate, fuse, freeze, heat, microwave, polish, etch, reduce, oxidize, hydroxylate, anneal, UV cure, e-beam cure and/or bake the surface or bulk of the channel layer 120. In addition to film processing directly on the surface or bulk structure of the channel layer 120 itself, in one or more embodiments, any of the film processing steps disclosed may also be performed on an underlayer formed on the channel layer 120 as disclosed in more detail below, and the term “channel surface” is intended to include such underlayer as the context indicates. Thus, for example, where a film/layer or partial film/layer has been deposited onto a channel surface, the exposed surface of the newly deposited film/layer becomes the channel surface.

Referring to FIG. 6, in one or more embodiments, after the channel layer 120 is deposited, the device 100 is patterned to form a plurality of openings 122. In some embodiments, the plurality of openings 122 extend from a top surface of the channel layer 120 to a top surface of the substrate 102 and a top surface of the dielectric material 104. In some embodiments, the patterning comprises a self-aligned quadruple patterning (SAQP) process.

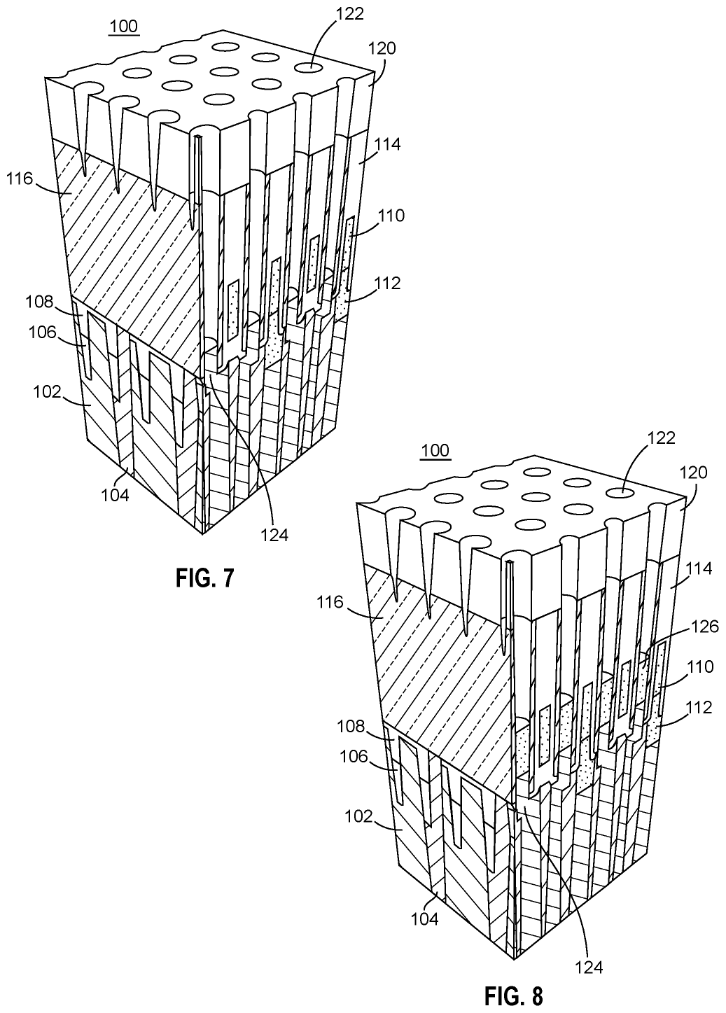

FIG. 7 illustrates a cross-section view of a DRAM device 100 according to one or more embodiments. With reference to FIG. 7, a poly-silicon or epi-silicon material 124 is grown in a bottom-up process to partially fill the plurality of openings 122.

FIG. 8 illustrates a cross-section view of a DRAM device 100 according to one or more embodiments. With reference to FIG. 8, a drain 126 is implanted in the plurality of openings 122 on a top surface of the poly-silicon or epi-silicon material 124. In one or more embodiments, the drain 126 comprises furnace or ALD or CVD deposited (undoped or doped) poly-silicon.

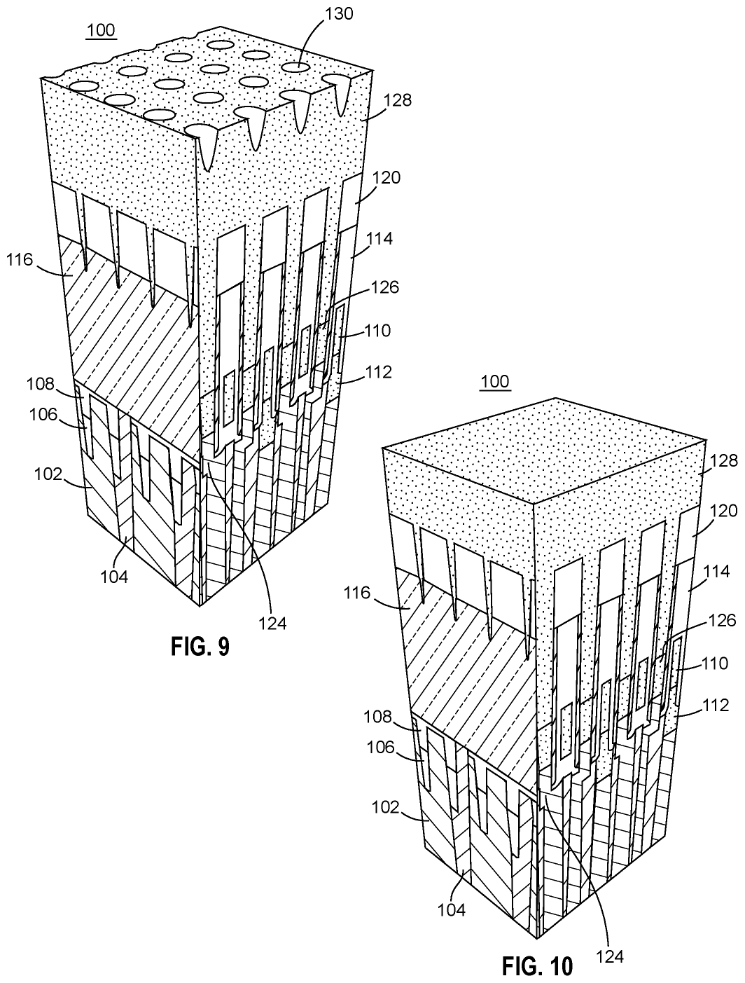

FIG. 9 illustrates a cross-section view of a DRAM device 100 according to one or more embodiments. With reference to FIG. 9, a second metal layer 128 is deposited on a top surface of the channel layer 120 and to fill the openings 122. In one or more embodiments, openings 130 are craters formed by non-planar or non-conformal metal fill.

In one or more embodiments, the second metal layer 128 can be made of any suitable material known to the skilled artisan. In one or more embodiments, the second metal layer 128 comprises a metal selected from one or more of copper (Cu), cobalt (Co), tungsten (W), titanium (Ti), molybdenum (Mo), nickel (Ni), ruthenium (Ru), silver (Ag), gold (Au), iridium (Ir), or platinum (Pt). In one or more specific embodiments, the second metal layer 128 comprises a metal selected from one or more of cobalt (Co), tungsten (W), titanium (Ti), molybdenum (Mo), nickel (Ni), ruthenium (Ru), silver (Ag), iridium (Ir), or platinum (Pt). In other specific embodiments, the second metal layer 128 comprises a metal selected from one or more of cobalt (Co), tungsten (W), titanium (Ti), molybdenum (Mo), or ruthenium (Ru).

In one or more embodiments, the second metal layer 128 forms an overburden when deposited, the overburden having plurality of openings 130. FIG. 10 illustrates a cross-section view of a DRAM device 100 according to one or more embodiments. With reference to FIG. 10, the overburden and plurality of openings 130 may be removed by any technique known to one of skill in the art, including, but not limited to chemical mechanical polishing (CMP), planarization, etch back, and the like. When the overburden is removed, the top surface of the second metal layer 130 is substantially smooth. As used in this manner, “substantially smooth” means that the plane formed by the top surface of the second metal layer 128 has less than 5% defects or openings in it.

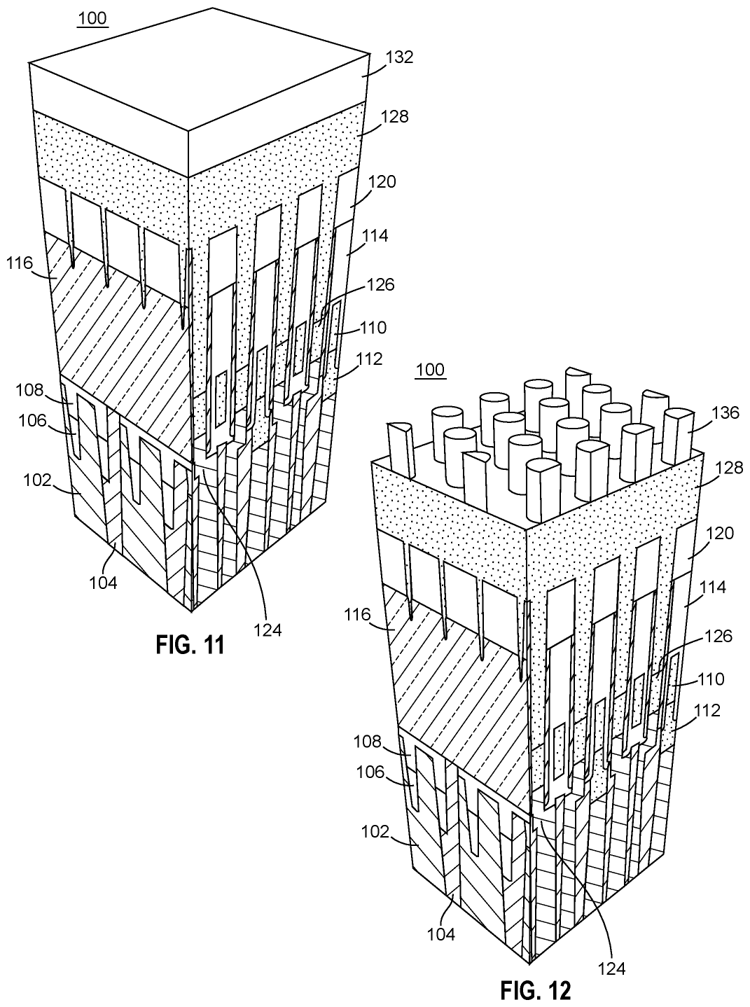

FIG. 11 illustrates a cross-section view of a DRAM device 100 according to one or more embodiments. With reference to FIG. 11, a hard mask layer 132 is deposited on a top surface of the second metal layer 128. The hard mask layer 132 can be deposited using one or more mask layer deposition techniques known to one of ordinary skill in the art of microelectronic device manufacturing. In one or more embodiments, the hard mask layer 132 is deposited using one of deposition techniques, such as, but not limited to, ALD, CVD, PVD, FCVD, MBE, MOCVD, spin-on, or other deposition techniques known to the skilled artisan. In one or more embodiments, the hard mask layer 132 comprises a material selected from one or more of spin-on carbon, hard mask, or a photoresist. The skilled artisan will understand that multiple hard mask layers 132 may be present. In one or more embodiments, the hard mask layer 132 comprises carbon hard mask.

In one or more embodiments, the hard mask layer 132 can be made of any suitable material known to the skilled artisan. In one or more embodiments, the hard mask layer 132 comprises one or more of oxides, carbon doped oxides, silicon oxide (SiO), porous silicon dioxide (SiO₂), silicon oxide (SiO), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH). In one or more embodiments, the hard mask layer 132 includes, without limitation, furnace, CVD, PVD, ALD and spin-on-coat (SoC) deposited films. In one or more embodiments, the hard mask layer 132 comprises silicon nitride (SiN). In one or more embodiments, the hard mask layer 132 may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the hard mask layer 132.

FIG. 12 illustrates a cross-section view of a DRAM device 100 according to one or more embodiments. With reference to FIG. 12, the hard mask layer 132 is patterned to form pillars 136 of the hard mask layer 132. In one or more embodiments, the pillars 136 have any shape known to the skilled artisan, including, but not limited to, rectangular, triangular, oval, rounded, hexagonal, and the like.

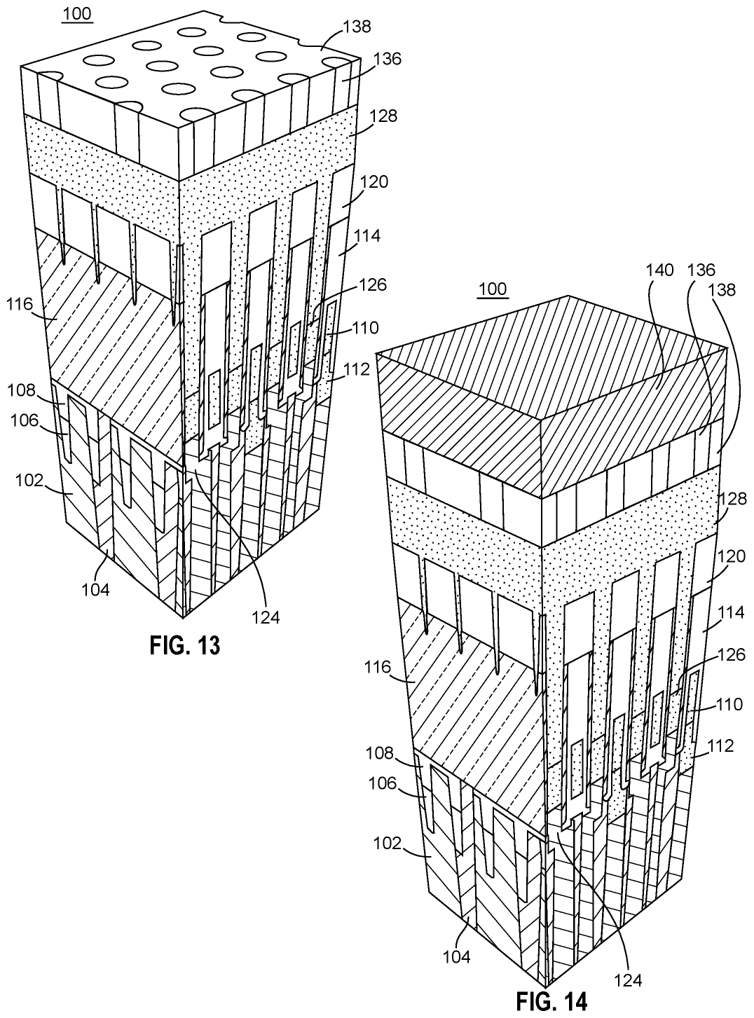

FIG. 13 illustrates a cross-section view of a DRAM device 100 according to one or more embodiments. With reference to FIG. 13, a hard mask layer 138 is deposited on and around the pillars 136. The hard mask layer 138 can be deposited using one or more mask layer deposition techniques known to one of ordinary skill in the art of microelectronic device manufacturing. In one or more embodiments, the hard mask layer 138 is deposited using one of deposition techniques, such as, but not limited to, ALD, CVD, PVD, FCVD, MBE, MOCVD, spin-on, or other deposition techniques known to the skilled artisan. In one or more embodiments, the hard mask layer 138 comprises a material selected from one or more of spin-on carbon, hard mask, or a photoresist. The skilled artisan will understand that multiple hard mask layers 138 may be present. In one or more embodiments, the hard mask layer 138 comprises silicon nitride (SiN).

FIG. 14 illustrates a cross-section view of a DRAM device 100 according to one or more embodiments. With reference to FIG. 14, a second hard mask layer 140 is deposited on a top surface of the hard mask layer 138 and the top surface of the pillars 136. The second hard mask layer 140 can be deposited using one or more mask layer deposition techniques known to one of ordinary skill in the art of microelectronic device manufacturing. In one or more embodiments, the second hard mask layer 140 is deposited using one of deposition techniques, such as, but not limited to, ALD, CVD, PVD, MBE, MOCVD, spin-on, or other deposition techniques known to the skilled artisan. In one or more embodiments, the second hard mask layer 140 comprises a material selected from one or more of spin-on carbon, hard mask, or a photoresist. The skilled artisan will understand that multiple second hard mask layers 140 may be present. In one or more embodiments, the second hard mask layer 140 comprises silicon oxide (SiO).

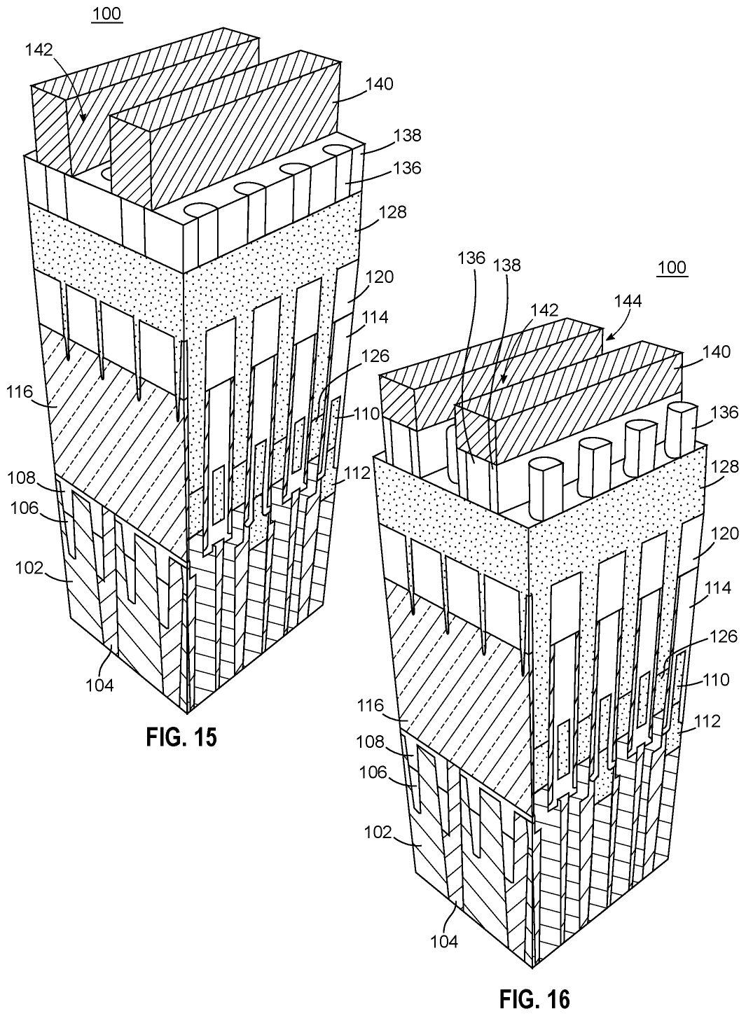

FIG. 15 illustrates a cross-section view of a DRAM device 100 according to one or more embodiments. With reference to FIG. 15, the second hard mask layer 140 is patterned. In one or more embodiments, the second hard mask layer 140 may be patterned by any patterning technique known to one of skill in the art. In some embodiments, the second hard mask layer 140 is patterned by self-aligned double patterning (SADP) processes. Patterning the second hard mask layer 140 forms opening 142 in the second hard mask layer 140 and exposes a top surface of the hard mask layer 138 and the top surface of the pillars 136.

FIG. 16 illustrates a cross-section view of a DRAM device 100 according to one or more embodiments. With reference to FIG. 16, the device 100 is patterned to increase the depth of the opening 142, exposing a top surface of the second metal layer 128 and exposing pillars 136. The patterning creates at least one landing pad stack 144, the landing pad stack 144 adjacent to the opening 142. In one or more embodiments, the landing pad stack 144 comprises the second hard mask layer 140 on a top surface of the pillar 136 and the hard mask layer 138, the hard mask layer 138 surrounding the pillars 136. In one or more embodiments, the landing pad stack 144 may be patterned by any patterning technique known to one of skill in the art. In some embodiments, the landing pad stack 144 is patterned by self-aligned double patterning (SADP) processes and with reactive ion etching or dry plasma etcher.

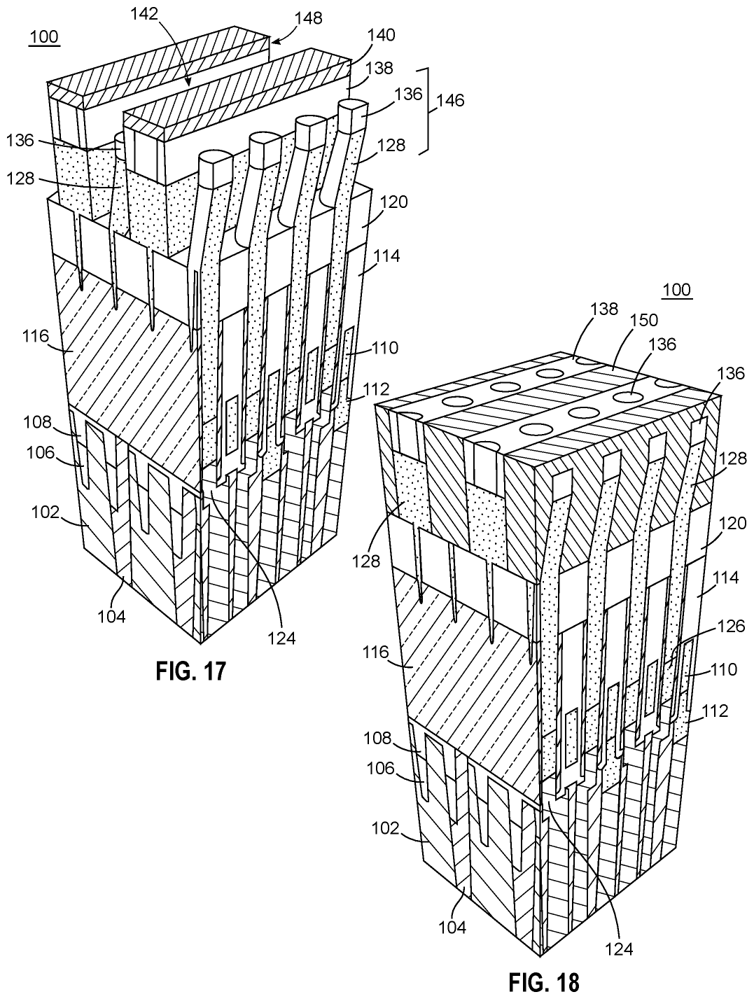

FIG. 17 illustrates a cross-section view of a DRAM device 100 according to one or more embodiments. With reference to FIG. 17, the device 100 is patterned in a first direction, using direction ion or electron beam etching tool, to increase the depth of the opening 142, exposing a top surface of the channel layer 120 and exposing first angled pillar 146. In one or more embodiments, the angled pillars 146 comprise a post of the second metal layer 128 and a cap of the pillar 136. In one or more embodiments, the angle of the first angled pillar 146 with respect to the top surface of the channel layer 120 is in a range of from about 1° to about 90°, including from about 1° to about 89°, and from about 5° to about 85°. The patterning creates at least one landing pad stack 148, the landing pad stack 148 adjacent to the opening 142. In one or more embodiments, the landing pad stack 148 comprises the second hard mask layer 140 on a top surface of the pillar 136 and the hard mask layer 138, the hard mask layer 138 surrounding the pillars 136, and the hard mask layer 138 and the pillars 136 on a top surface of the second metal layer 128.

FIG. 18 illustrates a cross-section view of a DRAM device 100 according to one or more embodiments. With reference to FIG. 18, a third hard mask layer 150 is deposited in the openings 142. In one or more embodiments, the third hard mask layer 150 is deposited using any deposition technique known to one of skill in the art, such as, but not limited to, ALD, CVD, PVD, FCVD, MBE, MOCVD, spin-on, shallow trench isolation (STI), or other deposition techniques known to the skilled artisan. In one or more embodiments, the third hard mask layer 150 forms an overburden (not illustrated) when deposited, and the overburden may be removed by any technique known to one of skill in the art, including, but not limited to chemical mechanical polishing (CMP), planarization, and the like. When the overburden is removed, the top surface of the third hard mask layer 150 is substantially coplanar with the top surface of the hard mask layer 138 and the top surface of the pillars 136.

As used in this manner, “substantially coplanar” means that the plane formed by the top surface of the third hard mask layer 150 is within ±5°, ±4°, ±3°, ±2° or ±1° of the plane formed by the top surface of the hard mask layer 138 and the top surface of the pillars 136. In some embodiments, the term “substantially coplanar” means that the planes formed plane formed by the top surface of the third hard mask layer 150 is within ±10 nm, ±5 nm, ±2.5 nm, ±1 nm or ±0.5 nm of the plane formed by the top surface of the hard mask layer 138 and the top surface of the pillars 136.

In one or more embodiments, the third hard mask layer 150 may comprise any suitable material known to one of skill in the art. In one or more embodiments, the third hard mask layer 150 comprises a material selected from one or more of spin-on carbon, hard mask, or a photoresist. The skilled artisan will understand that multiple hard mask layers 150 may be present. In one or more embodiments, the third hard mask layer 150 comprises silicon oxide (SiO).

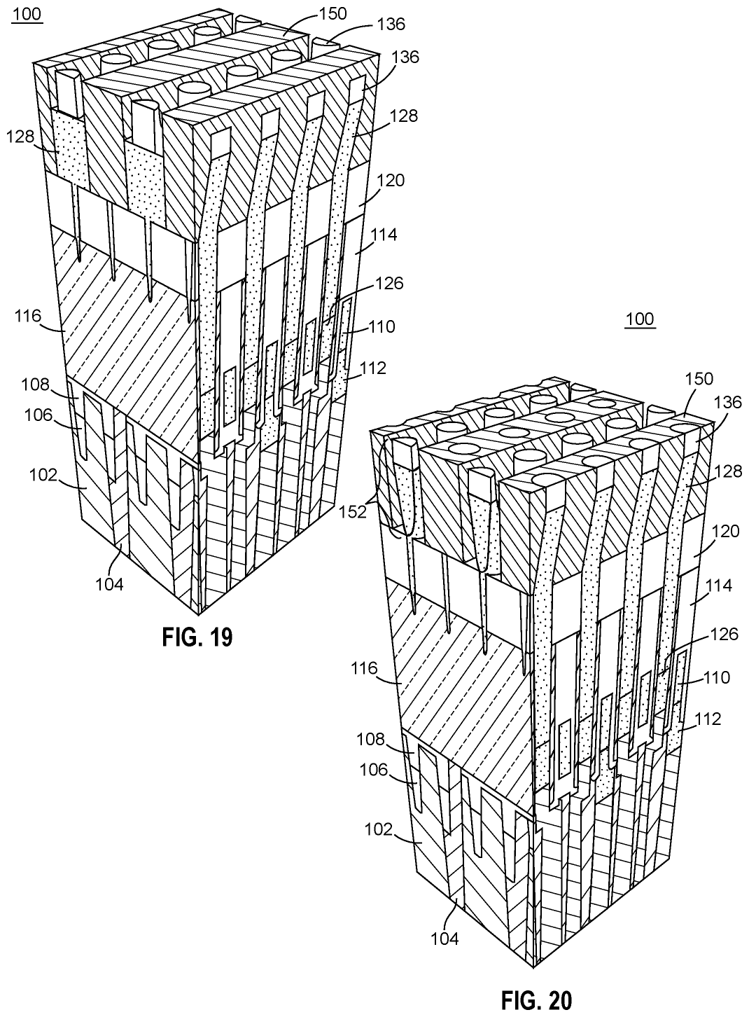

FIG. 19 illustrates a cross-section view of a DRAM device 100 according to one or more embodiments. With reference to FIG. 19, in one or more embodiments, the hard mask layer 138 is selectively removed to expose the pillars 136. In one or more embodiments, the hard mask layer 138 may be selectively removed using one or more of the dry and wet etching techniques known to one of ordinary skill in the art of electronic device manufacturing.

FIG. 20 illustrates a cross-section view of a DRAM device 100 according to one or more embodiments. With reference to FIG. 20, the device 100 is patterned in a second direction, using directional ion or electron beam etching tool, to remove a portion of the second metal layer and exposing second angled pillar 152. In one or more embodiments, the second angled pillar 152 comprises a post of the second metal layer 128 and a cap of the pillar 136. In one or more embodiments, the angle of the second angled pillar 152 with respect to the top surface of the channel layer 120 is in a range of from about 1° to about 90°, including from about 1° to about 89°, and from about 5° to about 85°. It should be noted that the second angled pillar 152 has an angle in a second direction opposite the first angled pillar 146 having an angle in the first direction. The patterning creates at least one second landing pad stack 153, the second landing pad stack 152 adjacent to the second angled pillar 152. In one or more embodiments, the second landing pad stack 153 comprises the third hard mask layer 150 on a top surface of the channel layer 120 and surrounding the first angled pillar 146.

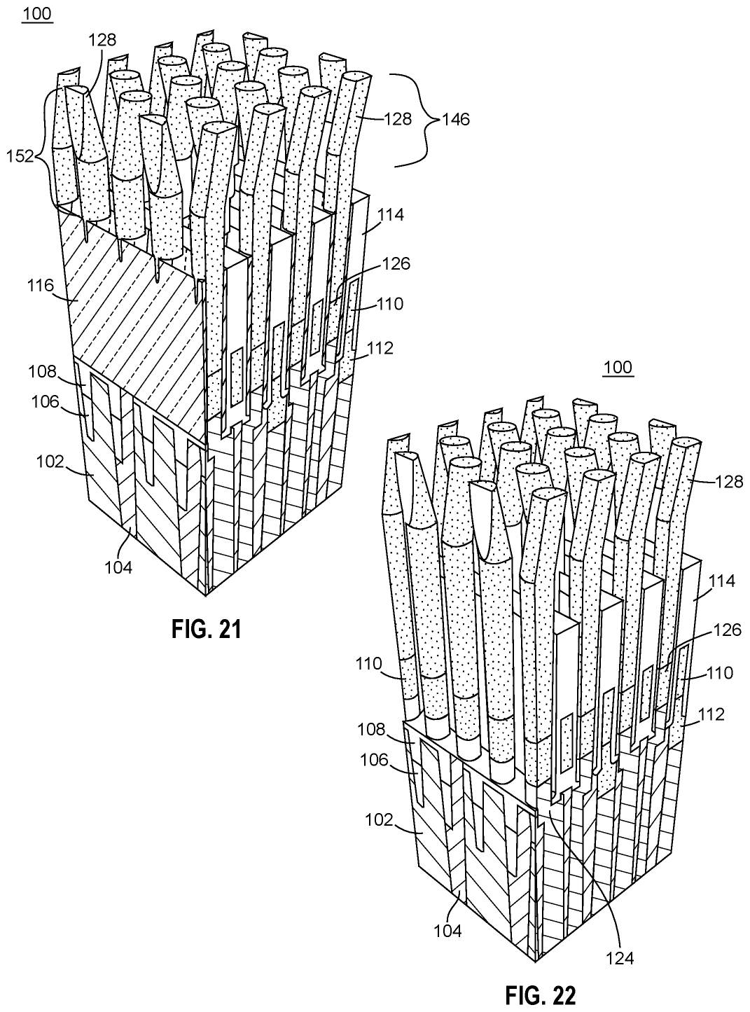

FIG. 21 illustrates a cross-section view of a DRAM device 100 according to one or more embodiments. With reference to FIG. 21, the third hard mask layer 150 is removed to expose the top surface of the gap fill layer 116 and a top surface of the liner 114. As illustrated in FIG. 21, removing the third hard mask layer 150 exposed both the first angled pillar 146 angled along the first direction and the second angled pillar 152 angled along the second direction. The device 100 illustrated in FIG. 21 advantageously has significantly less (up to 100% less) landing pad (LP) to storage node post (SnP) metal resistance, has improved electrical performance, and has higher sort yield. The device 100 illustrated in FIG. 21 advantageously allows for continuous DRAM pitch scaling beyond d13 node. In one or more embodiments, the device 100 illustrated in FIG. 21 uses two times looser pitch due to multiple patterning litho-etch-litho-etch split in landing pad (LP) patterning. In one or more embodiments, the landing pad with twin-directional e-beam and ion etching, as illustrated in FIG. 21, allow two times looser overlay budget and two times looser scanner MMO, such that patterning is less expensive. Point of reference (PoR) landing pad has about 50% less area for landing pad to land on SnC. The landing pad of one or more embodiments has about 100% surface contact between landing pad and SnC, thereby reducing scanner and overlay requirement by about two times.

Without intending to be bound by theory, it is thought that despite the fact that the e-beam and ion etch of one or more embodiments requires more patterning steps and more expensive toolset and longer learning, FabOut cycle time, the potential electrical performance gain justifies the additional processing steps. Furthermore, in one or more embodiments, the only overlay concern will be multiple patterning litho-etch-litho-etch, which can be managed with metrology and scanner matching.

FIG. 22 illustrates a cross-section view of a DRAM device 100 according to one or more embodiments. With reference to FIG. 22, the gap fill layer 116 is selective removed from the device 100, exposing a top surface of insulator layer 108. In one or more embodiments, the gap fill layer 116 may be selectively removed using one or more of the dry and wet etching techniques known to one of ordinary skill in the art of electronic device manufacturing.

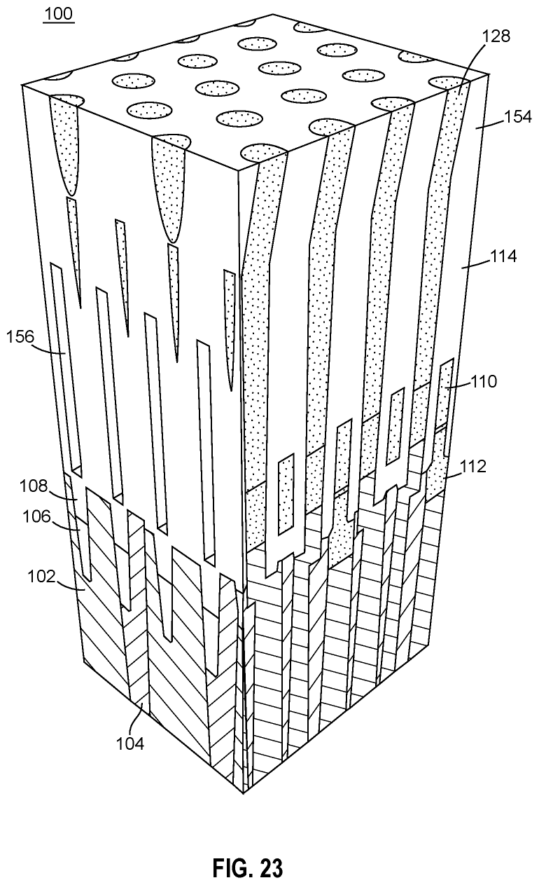

FIG. 23 illustrates a cross-section view of a DRAM device 100 according to one or more embodiments. With reference to FIG. 23, a second insulator layer 154 is deposited on and surrounding both the first angled pillar 146 angled along the first direction and the second angled pillar 152 angled along the second direction.

In one or more embodiments, the second insulator layer 154 forms an overburden (not illustrated) when deposited, and the overburden may be removed by any technique known to one of skill in the art, including, but not limited to chemical mechanical polishing (CMP), planarization, and the like. When the overburden is removed, the top surface of the second insulator layer 154 is substantially coplanar with the top surface of both the first angled pillar 146 angled along the first direction and the second angled pillar 152 angled along the second direction.

As used in this manner, “substantially coplanar” means that the plane formed by the top surface of the second insulator layer 154 is within ±5°, ±4°, ±3°, ±2° or ±1° of the plane formed by the top surface of both the first angled pillar 146 angled along the first direction and the second angled pillar 152 angled along the second direction. In some embodiments, the term “substantially coplanar” means that the planes formed plane formed by the top surface of the second insulator layer 154 is within ±10 nm, ±5 nm, ±2.5 nm, ±1 nm or ±0.5 nm of the plane formed by the top surface of both the first angled pillar 146 angled along the first direction and the second angled pillar 152 angled along the second direction.

In one or more embodiments, the second insulator layer 154 can be made of any suitable material known to the skilled artisan. In one or more embodiments, the second insulator layer 154 comprises one or more of oxides, carbon doped oxides, silicon oxide (SiO), porous silicon dioxide (SiO₂), silicon oxide (SiO), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH). In one or more embodiments, the second insulator layer 154 includes, without limitation, furnace, CVD, PVD, ALD and spin-on-coat (SoC) deposited films. In one or more embodiments, the second insulator layer 154 comprises silicon nitride (SiN). In one or more embodiments, the second insulator layer 154 may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the second insulator layer 154. In addition to film processing directly on the surface of the second insulator layer 154 itself, in one or more embodiments, any of the film processing steps disclosed may also be performed on an underlayer formed on the second insulator layer 154, and the term “insulator surface” is intended to include such underlayer as the context indicates. Thus, for example, where a film/layer or partial film/layer has been deposited onto an insulator surface, the exposed surface of the newly deposited film/layer becomes the insulator surface.

In one or more embodiments, when the second insulator layer 154 is deposited, and air gap 156 is formed, by tuning FCVD, CVD, PVD, SoC recipe to make a non-conformal or poorly conformal deposition. In some embodiments, the air gap extends from the top surface of the liner 114 to the top surface of the insulator layer 108.

In one or more embodiments, an integrated bit line air gap 156 is formed by removing the low-k surrounding the bit line, after the landing pad metallization steps are completed. In one or more embodiments, the volume of the air gap 156 is about four hundred times larger than traditional DRAM devices. The device 100 illustrated in FIG. 23 has four times lower BL-BL coupling, the potential for four times thinner aspect ratio capacitor; less expensive cost of operation because no etchant and residue cleaning steps are required; and a faster FabOut cycle time.

One or more embodiments are directed to a non-transitory computer readable medium including instructions, that, when executed by a controller of a processing chamber, causes the processing chamber to perform operations of: forming a liner on a top surface of a substrate, a word line, and a bit line; forming a low-k dielectric layer on the liner and surrounding the bit line; forming channel layer on the low-k dielectric layer; forming a drain region adjacent the word line; forming a landing pad on the channel layer; and patterning the landing pad to form a plurality of first angled pillars and a plurality of second angled pillars.

In one or more embodiments, the method further includes instructions that, when executed by a controller of a processing chamber, causes the processing chamber to perform operations of forming at least one air gap adjacent the channel and the bit line on the source region.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A memory device comprising:
a substrate having a length extending along a first direction, a width extending along a second direction and a height extending along a third direction, the substrate comprising a channel and a dielectric material;
a word line extending along the first direction, the word line comprising a word line metal and a first insulating material;
a gate oxide extending along the first direction and in electrical communication with the word line;
a bit line extending along the second direction, the bit line comprising a bit line metal and a second insulating material; and
a landing pad on a top surface of the low-k dielectric and the bit line, the landing pad comprising a plurality of first angled pillars and a plurality of second angled pillars.

2. The memory device of claim 1, wherein the plurality of first angled pillars are angled in the first direction, and the plurality of the second angled pillars are angled in a direction opposite the plurality of first angled pillars.

3. The memory device of claim 2, further comprising a dielectric surrounding the bit line, wherein the dielectric comprises one or more of a low-k dielectric, SiN, SiO, TiO₂, and Al₂O₃.

4. The memory device of claim 3, wherein the first angled pillars have an angle in a range of from 1° to about 89° relative to the top surface of the storage node contact.

5. The memory device of claim 3, wherein the second angled pillars have an angle in a range of from 1° to about 89° relative to the top surface of the storage node contact.

6. The memory device of claim 1, wherein the word line and bit line independently comprise one or more of copper (Cu), cobalt (Co), tungsten (W), aluminum (Al), ruthenium (Ru), iridium (Ir), molybdenum (Mo), platinum (Pt), tantalum (Ta), titanium (Ti), rhodium (Rh), and titanium nitride (TiN).

7. The memory device of claim 6, wherein the bit line and word line independently comprise one or more of ruthenium (Ru), molybdenum (Mo), and tungsten (W).

8. The memory device of claim 1, wherein the gate oxide comprises silicon oxide.

9. The memory device of claim 2, wherein the low-k dielectric comprises one or more of silicon, silicon oxide, silicon nitride, silicon oxynitride, silicon oxycarbide, silicon oxycarbonitride, doped silicon, doped silicon oxide, doped silicon nitride, doped silicon oxynitride, spin-on dielectrics, and a diffusion species growth.

10. The memory device of claim 1, wherein the channel comprises silicon, polysilicon, germanium, indium phosphate, gallium nitride, gallium arsenide, 2D moly disulfide, silicon germanium and the dielectric comprises silicon oxide.

11. The memory device of claim 1, further comprising a third insulating material surrounding the landing pad.

12. The memory device of claim 11, further comprising an air gap in the third insulating material, the air gap extending along the third direction.

13. A method of forming a semiconductor device, the method comprising:
forming a liner on a top surface of a substrate, a word line, and a bit line;
forming a low-k dielectric layer on the liner and surrounding the bit line;
forming channel layer on the low-k dielectric layer;
forming a drain region adjacent the word line;
forming a landing pad on the channel layer; and
patterning the landing pad to form a plurality of first angled pillars and a plurality of second angled pillars.

14. The method of claim 13, wherein patterning the landing pad comprises e-beam and ion etching of the landing pad in a first direction and e-beam and ion etching of the landing pad in a second direction.

15. The method of claim 13, wherein the substrate comprises a channel and a dielectric material.

16. The method of claim 13, wherein the word line comprises a word line metal and a first insulating material.

17. The method of claim 13, wherein the bit line comprises a bit line metal and a second insulating material.

18. The method of claim 14, further comprising forming at least one air gap adjacent the channel and the bit line on the source region.

19. The method of claim 13, further comprising:
selectively removing the low-k dielectric layer; and
depositing a third insulating layer on the plurality of first angled pillars and the plurality of second angled pillars to form a plurality of air gaps in the third insulating layer.

20. A non-transitory computer readable medium including instructions, that, when executed by a controller of a processing chamber, causes the processing chamber to perform operations of:
forming a liner on a top surface of a substrate, a word line, and a bit line;
forming a low-k dielectric layer on the liner and surrounding the bit line;
forming channel layer on the low-k dielectric layer;
forming a drain region adjacent the word line;
forming a landing pad on the channel layer; and
patterning the landing pad to form a plurality of first angled pillars and a plurality of second angled pillars.
